(19) United States
(12) Patent Application Publication
(10) Pub. No.: US 2024/0102164 A1
(43) Pub. Date: Mar. 28, 2024

(54) CVD REACTOR COMPRISING A PROCESS CHAMBER FLOOR RISING IN A FEEDER ZONE

(71) Applicant: AIXTRON SE, Herzogenrath (DE)

(72) Inventor: Levin David Richard Johannes BEE, Raeren (BE)

(21) Appl. No.: 18/275,764

(22) PCT Filed: Feb. 4, 2022
(86) PCT No.: PCT/EP2022/052660

§ 371 Date: Aug. 3, 2023

(30) Foreign Application Priority Data
Feb. 11, 2021 (DE) 10 2021 103 245.8

(51) Int. Cl. C23C 16/455; C23C 16/458

(52) U.S. Cl. CPC C23C 16/45572; C23C 16/45508; C23C 16/4584

(57) ABSTRACT

A CVD reactor comprising a gas inlet element which has a cooling device and gas outlet openings which lead into a process chamber. The process chamber has a feeder zone directly adjoining the gas inlet element and a process zone with one or more substrate holders. The process zone follows the feeder zone in a flow direction of a process gas entering the process chamber from the gas outlet openings. The feeder zone has a first floor portion directly adjoining the gas inlet element and a second floor portion located between the first floor portion and the process zone. In order to prevent the formation of parasitic coatings during deposition of, for example, silicon carbide at the start of the feeder zone, the first floor portion rises in the flow direction, so that the height of the process chamber initially decreases starting from the gas inlet element.

### RELATED APPLICATIONS

This application is a National Stage under 35 USC 371 of and claims priority to International Application No. PCT/EP2022/052660, filed 4 Feb. 2022, which claims the priority benefit of DE Application No. 10 2021 103 245.8, filed 11 Feb. 2021.

### FIELD OF THE INVENTION

The invention relates to a CVD reactor comprising a gas inlet element, which has a cooling device and which has gas outlet openings leading into a process chamber, wherein the process chamber has a feeder zone directly adjoining the gas inlet element and a process zone, which follows said feeder zone in a flow direction of a process gas entering the process chamber from the gas outlet openings and in which one or several storage spaces for storing substrates are arranged, wherein the feeder zone has a first floor portion, which directly adjoins the gas inlet element and has a second floor portion, which is arranged between the first floor portion and the process zone.

The invention furthermore relates to an annular body that can be used in a CVD reactor.

### BACKGROUND

A CVD reactor of the generic type is described in the DE 10 2014 104 218 A1. A process chamber, which is limited to the top from the underside of a process chamber ceiling and to the bottom by a top side of a susceptor, is arranged in a housing, which is gas-tight to the outside. Process gases are fed into the process chamber by means of a gas inlet element, which can be arranged in the center of the process chamber. The process gases are preferably hydrides and/or chlorides of the IV main group. However, the process gases can also be hydrides of the V main group and organometallic compounds of the III main group or elements of the II and VI main group. The process gases are fed into the process chamber through gas outlet openings of the gas inlet element by means of a carrier gas, for example hydrogen or nitrogen, or a noble gas. The gas inlet element is cooled by means of a cooling agent, in particular a liquid cooling agent, in order to prevent the process gases from decomposing within the gas inlet element or reacting with one another, respectively. For this purpose, it can be provided that a gas outlet wall of the gas inlet element has cooling ducts, through which a cooling agent flows. A lower portion of the gas inlet element can have a cooling agent distribution chamber, by means of which the cooling agent is distributed into the cooling ducts. The lower portion of the gas inlet element can lie in a depression of the susceptor. The depression can also be surrounded by a ring or can be formed by an annular part. The ring or the annular part forms a first floor portion of a feeder zone, which is followed by a second floor portion of the feeder zone in a flow direction of the process gas through the process chamber. The second floor portion adjoins a process portion, in which the substrates, which are to be coated, are located. The susceptor, which consists of graphite or another electrically conductive and/or thermally conductive material, is heated from below by means of a heating device. The substrates located on substrate carriers are heated to a process temperature by means of the heat supplied by the heating device. A first heat flow develops from the susceptor through the process chamber to the process chamber ceiling, and a second heat flow from the process zone through the feeder zone towards the cooled gas inlet element. It is known from the prior art to influence the feeder zone temperature by means of suitable measures, in order to prevent parasitic coatings of reaction products of the process gases from forming there.

### SUMMARY OF THE INVENTION

The invention is based on the object of specifying measures, by means of which the formation of parasitic coatings can be reduced in the region of the feeder zone upstream of the flow.

The object is solved by means of the invention, which is specified in the claims, wherein the subclaims are not only advantageous further developments of the solution specified in claim 1, but also represent independent solutions of the object.

In the case of the above-mentioned CVD reactor of the prior art, the portion of the gas inlet element having a cooling agent chamber protrudes into a depression, which forms a step-shaped edge. The process chamber floor extends from a radially innermost region directly adjoining the gas inlet element all the way into the process zone at a uniform level, so that the height of the process chamber has a uniform value over the entire process chamber.

According to the invention, the floor of the process chamber in the first floor portion directly adjoining the gas inlet element should not have a uniform level but rather should rise in the flow direction and should in particular rise from a first level to a second level, so that the process chamber height decreases in the region of the first portion with increasing distance from the gas inlet element. The first level can be defined by the depression floor or by a plane of the lower front side of the gas inlet element or by the height of a step. The second level can be defined by the level at which the surface of the susceptor facing the process chamber, or surfaces of cover plates resting on the susceptor, or surfaces of the substrates to be coated extend. It is in particular provided that the feeder zone extends from the gas inlet element all the way to the storage spaces for receiving the substrates. The length of the feeder zone can thus be defined by the distance of at least one storage space to the gas inlet element. An extension length of the first floor portion, which rises in the flow direction, can be defined by the distance of the beginning of the second level from the gas inlet element. The first floor portion rising in the flow direction can transition into the second floor portion by forming a transition edge. However, it can also transition into the second floor portion in a bending point-free manner. The first floor portion can run in a hollow or convex manner. However, it can also rise in a stair-shaped manner. A smooth course of the floor portion, which is free from bending points, is preferred in order to avoid vortex formation of the process gas flowing over it. In the case of exemplary embodiments of the invention, it is provided that the first floor portion runs in a straight line in the cross section. The first floor portion can rise in a straight line from the gas inlet element all the way to a transition region, for example a transition edge. If the gas inlet element is located in the center of a process chamber, the first floor portion can be formed by a conical surface, which surrounds the gas inlet element. In the case of some exemplary embodiments of the invention, it is provided that the first floor portion extends over at least 10%, at least 20%, or 30%+/−5% over the length of the feeder zone. As a result of the design according to the invention of the feeder zone, the region of the first floor portion directly adjoining the gas inlet element can cool down less than in the case of a step-shaped transition from the floor of the process chamber towards the depression floor. A reduction of the coating of the first floor portion with decomposition products is attained by means of the bevel according to the invention of the first floor portion. An edge of the gas inlet element running in particular on a circular arc-shaped line, which is defined by a corner, at which the preferably cylinder jacket-shaped gas outlet wall adjoins a front surface of the gas inlet element facing downwards, can have a distance to the first floor portion, which runs in particular obliquely. The edge can be spatially spaced apart from an edge of a step, which defines the beginning of the first floor portion. This distance is the minimal distance of the first floor portion to the gas inlet element. The point in a cross sectional illustration, at which the step transitions into the first floor portion, can lie below a level, which is defined by the front surface of the gas inlet element facing downwards. The first floor portion rises continuously with increasing distance from the gas inlet element, until it has reached its maximum height. This height preferably corresponds to the level, on which the storage spaces for the substrates are located. It lies above the front surface of the gas inlet element facing downwards. The angle of the inclined first floor portion compared to the second floor portion adjoining in the flow direction can lie in the range between 5 degrees and 20 degrees, preferably in a range between 10 and 25 degrees or 15 and 20 degrees.

The underside of the process chamber ceiling can extend in a planar manner in one plane. This plane can run parallel and at a distance from the floor of the process zone of the process chamber. The underside of the process chamber ceiling can also run parallel to a radially outer second floor portion of the feeder zone. The second floor portion of the feeder zone can run at the same level, on which the floor of the process chamber extends in the process zone as well. The process chamber has a consistent height in these portions of the process chamber. In a direction towards the gas inlet element, the height of the process chamber increases continuously or gradually over the region of the first floor portion of the feeder zone, which runs in particular obliquely. In the flow direction, the process chamber height thus decreases continuously or gradually over the extension length of the first floor portion. The gas inlet element is preferably arranged in the center of the susceptor, which can be rotated with respect to the gas inlet element. The depression floor can have a distance to the underside of the gas inlet element, so that the susceptor can rotate freely with respect to the gas inlet element. The first floor portion can form an annular surface, which extends around the gas inlet element and which runs conically. The first floor portion can be formed by an annular element, which rests on a base body of the susceptor. The susceptor can be supported by a shaft, which can be rotationally driven. The first floor portion can also be formed by a pulling plate, by means of which the susceptor is fastened to the shaft. This pulling plate can have a circular disk-shaped shape. The pulling plate can form a central depression, into which the gas inlet element can protrude. The edge of the depression forms the first floor portion and can rise obliquely to the outside in the radial direction. The first floor portion can transition into a second floor portion, which extends in a plane. The annular element or a disk-shaped central element can be surrounded by cover elements, which cover a surface of the base body of the susceptor, which extends between the radially outer edge of the annular element or the disk-shaped central element and the substrate holders, respectively. The substate holders can be arranged in pockets of the susceptor or of cover elements, respectively. Gas outlet openings, from which a flushing gas can escape, can lead into the floors of the pockets, in order to hold the substrate holders in a balance or in order to rotationally drive the substrate holders about their figure axis, respectively.

The gas inlet element can consist of metal, ceramic, quartz, or another suitable material. It can form a cylinder jacket-shaped as outlet wall. Several gas outlet zones can be provided, which are arranged one on top of the other and which are in each case flow-connected with gas outlet openings in the gas outlet wall to the process chamber surrounding the gas inlet element, so that different process gases can be fed at different heights into the process chamber from the different gas outlet zones. Cooling agent ducts can run in the gas outlet wall, in order to cool the gas outlet wall. In a lower region, which preferably lies completely in the depression, a cooling agent chamber can be located, by means of which a liquid cooling agent, which is fed into the cooling agent chamber through a supply line, is distributed to cooling ducts. The cooling agent chamber can have an upper wall, which runs parallel to a floor of the gas inlet element and which separates the cooling agent chamber from a gas inlet zone located directly thereabove. The separating wall separating the cooling agent chamber from the gas inlet zone located directly thereabove, can lie at the same level, at which the level of the second floor portion or of the floor of the process zone, respectively, extends as well. The underside of the cooling agent chamber or the lower wall of the gas inlet element, respectively, or the depression floor can define a further level. The floor of the process chamber extends in the first floor portion rising from the lowermost of the two levels to the uppermost of the two levels. This increases the distance between the lower region of the outer wall of the gas inlet element, thus in particular of the outer wall of the cooling agent chamber, and the surface of the first floor portion facing the process chamber.

An annular body according to the invention can be used in an above-described CVD reactor. The inner diameter of the annular body is greater than the outer diameter of a gas inlet element. The outer diameter of the annular body is smaller than the inner diameter of a one- or multi-piece cover element, which surrounds the annular body. It is preferably provided that the annular body can be placed onto a flat bearing surface of a base body. A hollow cone surface adjoins the radially inner edge of the annular body. The hollow cone surface preferably originates from a radially inner wall, which extends on an inner cylinder surface. The height of this wall is preferably smaller than 50% of the material thickness of the annular body. Between the radially inner edge and the radially outer edge of the annular body, the hollow cone surface representing an oblique outer edge of the cross sectional surface in a cross sectional illustration transitions into a flat surface, which preferably runs parallel to the underside of the annular body, by forming a transition.

The invention furthermore relates to a use of an annular body of this type in a CVD reactor in order to reduce parasitic coatings in the feeder zone.

### BRIEF DESCRIPTION OF THE DRAWINGS

Exemplary embodiments of the invention will be described below with reference to the drawings, in which:

FIG. 1 schematically shows the section through the elements of a CVD reactor of a first exemplary embodiment, which limits a process chamber 2,

FIG. 2 shows a section according to the line II-II in

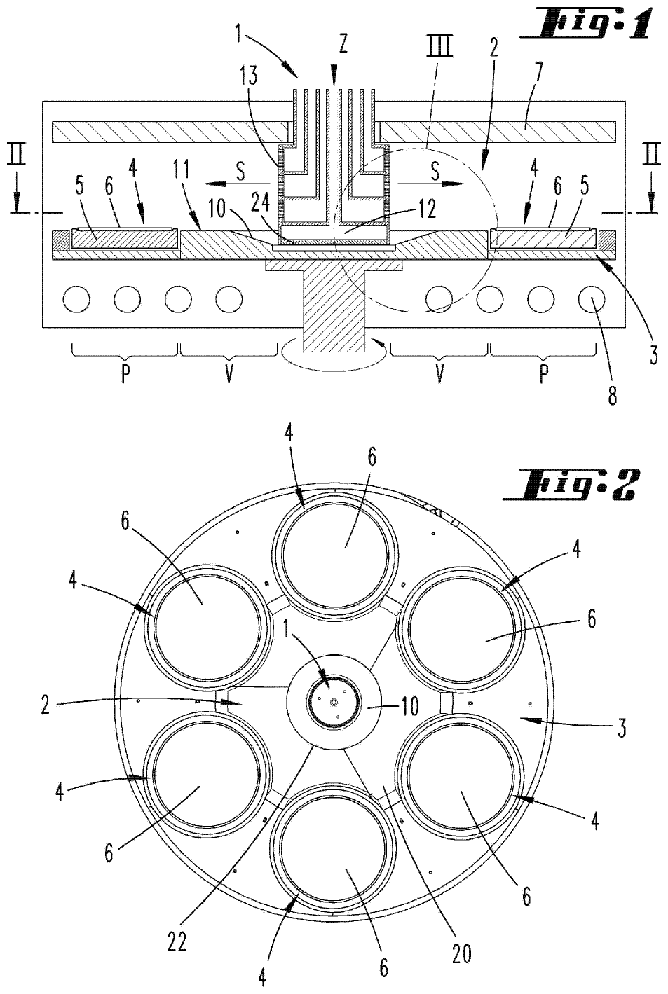

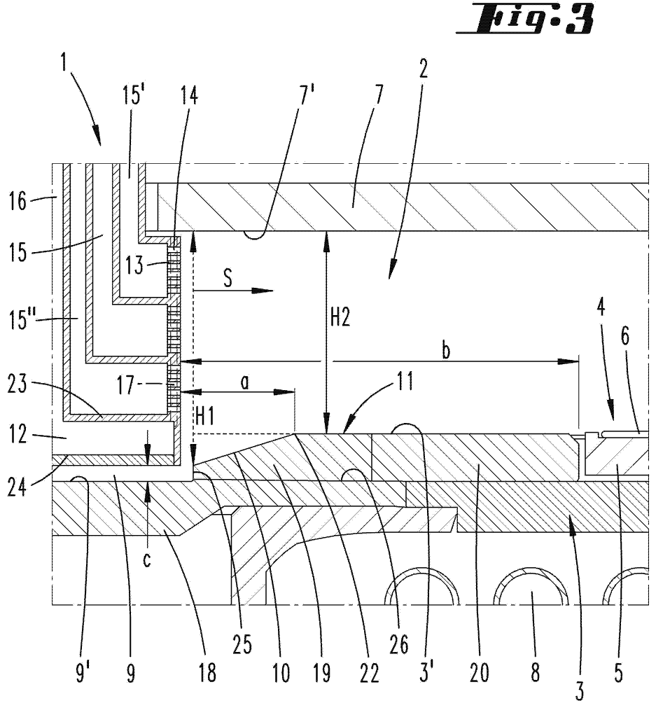

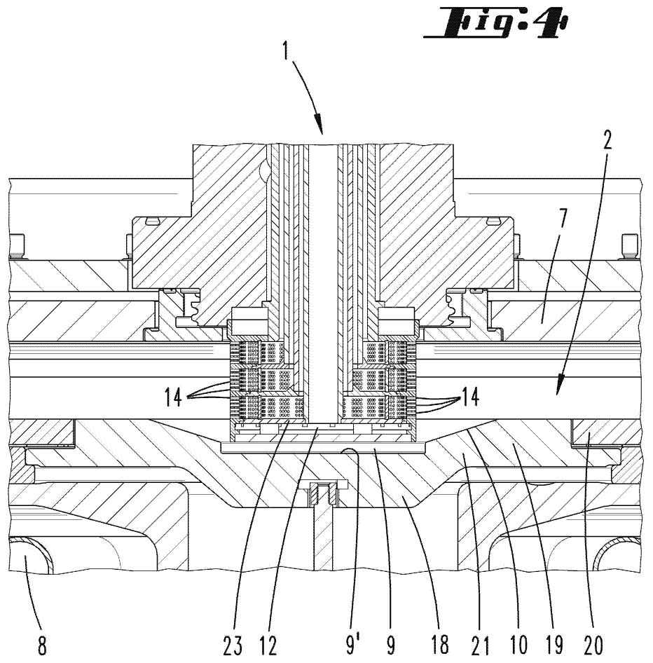

FIG. 1,

FIG. 3 shows the section III in FIG. 1 in an enlarged manner,

FIG. 4 shows an illustration similar to FIG. 3 of a second exemplary embodiment.

### DETAILED DESCRIPTION

The CVD reactor illustrated in the drawings essentially corresponds to a CVD reactor according to the reactor disclosed in the DE 10 2014 104 218 A1 or according to the publications cited on the cover sheet of this application. The content of these publications is thus included in its entirety into the disclosure content of this application, in particular in order to add features of the descriptions into the claims of this application. Further exemplary embodiments, which are not illustrated in the drawings, differ from the exemplary embodiments illustrated in the drawings by other ratios of height to width of the process chamber or by other ratios of length of the feeder zone and length of the process zone.

A CVD reactor of the type according to the invention has a gas-tight housing, in particular consisting of stainless steel, into which several gas supply lines lead and which has at least one gas discharge line. Process gases, for example hydrides, halides, or organometallic compounds of the IV main group can be fed in by means of the gas supply lines, which are not illustrated in the drawings. However, hydrides of the elements of the III main group and organometallic compounds of the elements of the V main group can also be fed into a gas inlet element 1. The gas inlet element has several gas inlet zones 15, 15′, 15″, which are arranged one on top of the other and into which the process gases can in each case be fed together with a carrier gas. The gas inlet zones 15, 15′, 15″ are surrounded by a gas outlet wall 13, which has gas outlet openings 14, through which the process gases can flow into the process chamber 2 surrounding the gas inlet element. The process gases flow through the process chamber 2 in a flow direction S all the way to a non-illustrated gas outlet element.

The gas inlet element 1 has a cooling agent duct 16, which is connected to a cooling agent chamber 12 in the region of the lowermost portion of the gas inlet element 1. A lower limiting wall 24 of the cooling agent chamber 12 forms a lower front surface of the gas inlet element 1. The cooling agent chamber 12 forms a cooling agent distributor in order to distribute the cooling agent into cooling agent ducts 17 of the gas outlet wall 13. The gas inlet element 1 is cooled to temperatures, at which a pre-decomposition of the process gases is avoided, by means of the liquid cooling agent flowing through the cooling agent ducts 16, 17 and the cooling agent chamber 12.

A base plate 18 of a susceptor 3 is located below the gas inlet element 1. The base plate 18 is illustrated in one piece in FIGS. 1 and 3. However, it can also be formed in several pieces and can in particular have parts, which are radially nested inside each other. The susceptor 3 extends around a center Z, wherein the center Z lies in the center of the gas inlet element 1.

The susceptor 3 can be rotationally driven around the center Z. For this purpose, the susceptor 3 can be supported by a shaft, which can be rotationally driven about its axis.

In the region of the center Z, the susceptor 3 or the one- or multi-piece base plate 18, respectively, has a depression 9 comprising a depression floor 9′. The depression floor 9′ is spaced apart from a flat underside of the gas inlet element 1 or the lower wall 24, respectively, at a distance c.

Several annular bodies 19, 20, which are nested inside each other, lie on the region of the base body 18 surrounding the gas inlet element. It is also possible, however, that the gas inlet element 1 is surrounded only by an annular body. The at least one annular body 19, 20 extends over a radial distance b around the gas inlet element 1. The radial distance b can be the length of a feeder zone V, which is measured in the flow direction S. The feeder zone V extends over the distance of the process chamber 2, which extends between gas inlet element 1 and the one or several storage spaces 4 for storing substrates 6 to be coated. The storage spaces 4 can be formed by substrate holders 5, which can rest on gas cushions in the known manner and which can be rotationally driven by gas flows.

While an inner annular body 19 can be formed in one piece, an outer annular body 20 can be formed in one or several pieces. The outer annular body 20 can have a radially inner limit line running on a circular arc-shaped line. The radially outer limit line can deviate from a circular arc shape and can at least partially comprise, for example, the pockets for receiving the substrate holders 5. It can also be provided, however, that the inner annular body 19 is formed in several pieces and in particular of elements, which are designed identically and which are arranged in the circumferential direction around the gas inlet element 1.

An inner ring 19 can adjoin, for example, one or several cover elements 20, which, in turn, adjoin the storage spaces 4 or the substrate carriers 5 forming the storage spaces 4. Several substrate holders 5 are provided, which are arranged on a circumferential line around the center.

According to the invention, the process chamber 2 has a region 10, which directly adjoins the gas inlet element 1 and which forms a first floor portion, which has a radial length a, which corresponds to at least 10% of the radial length b of the feeder zone V. The radial length a is preferably at least 20% or at least 30% of the radial length of the feeder zone V. In a particularly preferred design of the invention, the radial length is approximately 30% of the radial length of the feeder zone V. With respect to a horizontal plane, the surface of the first floor portion 10 can be inclined by an angle of 10 degrees to 25 degrees. However, smaller or larger angles of inclination are provided as well. A preferred angle of inclination is 17.5 degrees.

The region 10 directly adjoining the gas inlet element 1 differs from the region 11 of the process chamber floor 3′, which is radially farther on the outside, in that the region 11 father on the outside runs in a plane. The region 10 directly adjoining the gas inlet element 1 rises in the direction of the flow direction S. In the case of non-illustrated exemplary embodiments, the region 10 can rise in a stair-shaped, hollow-curved or convexly-curved manner. In the case of the exemplary embodiment, the floor of the process chamber 2 runs in the region of the floor portion 10 in a cross sectional illustration along a line, which is inclined obliquely to a rotational plane of the susceptor 3 and which is preferably a straight line. As a result of the obliquely running region, the height of the process chamber 2, directly adjoining the gas inlet element 1, has a first height H1, which is greater than a second height H2 of the process chamber 2 in the region of a second floor portion 11 adjoining the first floor portion 10.

The depression floor 9′ can define a first level, which is farther away from a comparative level defined by the course of the underside 7′ of the process chamber ceiling 7 than a second level of the process chamber floor, in which the radially outer region of the feeder zone V or the process zone P, respectively, extends. The second level can run approximately at the height of a separating wall 23 between lowermost gas inlet zone 15 and cooling agent chamber 12. The beginning of the rising region of the first floor portion 10 can be formed by a small step, with which the depression floor 9′ transitions into the rising floor portion 10. The angle of the inclined surface of the first floor portion 10 with respect to the plane, which surrounds the first floor portion 10 and which is formed by the second floor portion 11, is selected so that vortices do not form at a transition edge 22 between the first floor portion 10 and the second floor portion 11. The floor portion 10 thus preferably runs at an incline to the second floor portion 11 in such a way that a laminar flow forms over the floor portions 10 and 11.

In the case of the exemplary embodiment illustrated in FIG. 3, the rise of the first, inclined floor portion 10 starts at the level of the front surface of the gas inlet element 1 facing to the bottom, thus approximately in the region of the lower wall 24. The inclined floor portion 10 extends all the way to a higher level, which lies below a separating wall 23, thus in the region of the cooling agent chamber 12. However, this level can also lie at the level of the separating wall 23, which separates the cooling agent chamber 12 from the gas inlet zone 15″. In a preferred design, the ring 19 is formed of uniform material by a base body 18 formed as pulling plate 21. An outer portion of the pulling plate 21 can engage below a cover element 20, as shown in FIG. 4. A pulling element, by means of which force is applied to the pulling plate 21 towards the bottom in the direction of the shaft, engages in the center of the pulling plate 21.

The device according to the invention is particularly suitable for separating SiC and in particular of doped SiC. During this process, the feeder zone V has a critical influence on the doping material incorporation. Due to the enlarged distance, in particular of the first floor portion 10, from the gas inlet element 1, a separation of decomposition products of the process gases from the process zone is effectively reduced. Even though efforts are generally made in the case of the reactor design to provide the process chamber with a height, which remains constant over its entire extension, it came as a surprise that a height reduction of the process chamber in the region directly adjoining the gas inlet element 1 leads to a reduction of the depletion of the gas phase by means of pre-deposition.

The above statements serve to describe the inventions, which are captured by the application as a whole and which further develop the prior art at least by means of the following feature combinations, in each case also independently, whereby two, several, or all of these feature combinations can also be combined, namely:

A CVD reactor, which is characterized in that the first floor portion 10 rises in the flow direction S.

A CVD reactor, which is characterized in that the first floor portion 10 rises over an extension length a of the first floor portion 10 of at least 10%, at least 20%, or 30%+/−5% of the length b of the feeder zone V and/or rises at an angle of 10 to 25 degrees from a first level, in which a depression floor 9′ of a depression 9 lies, into which the gas inlet element 1 protrudes, or in which a lower wall 24 of the gas inlet element 1 lies, to a second level, in which the second floor portion 11 lies.

A CVD reactor, which is characterized in that a planar underside 7′ of a process chamber ceiling 7 has a first distance height H1 at the beginning of the first floor portion 11, viewed in the flow direction, and a second distance height H2 at the end of the first floor portion or at the beginning of the second floor portion 11, respectively, and/or runs parallel to a top side of substrate carriers 5 facing towards the process chamber 2, and/or that the distance of the process chamber ceiling 7 decreases continuously or gradually from a first distance height H1 all the way to a second distance height H2 with increasing distance from the gas inlet element 1 over an extension length a of the first floor portion 10.

A CVD reactor, which is characterized in that the gas inlet element 1 is arranged in the center Z of the process chamber 2, several substrate carriers 5 are arranged annularly around the gas inlet element 1 in the process zone P, and the first floor portion 10 forms an annular surface surrounding the gas inlet element 1.

A CVD reactor, which is characterized in that the surface of the first floor portion 10 facing the process chamber 2 runs in a smooth manner and/or, except for only one transition edge 22, in a bending point-free manner.

A CVD reactor, which is characterized in that the first floor portion 10 is formed by an inner ring 19, which is arranged around the gas inlet element 1 and which rests on a base body 18 of the susceptor 3 and/or that an inner ring 19 forming the first floor portion 10 is surrounded by one or several cover elements 20, which adjoin cover elements 20 on storage spaces 4.

A CVD reactor, which is characterized in that the first floor portion 10 is formed by a disk-shaped central element 21, which forms a depression 9 of uniform material, into which the gas inlet element 1 protrudes.

A CVD reactor, which is characterized in that the gas inlet element 1 has several gas inlet zones 15, 15′, which are arranged one on top of the other and which each have gas outlet openings 14 arranged on a cylinder jacket surface and/or that the gas outlet openings 14 are arranged in a gas outlet wall 13 of the gas inlet element 1 having one or several cooling agent ducts 17 and/or that a cooling agent chamber 12 is arranged below one or several gas inlet zones 15, 15′, 15″ of the gas inlet element 1, wherein the portion of the gas inlet element 1, in which the cooling agent chamber 12 lies, is arranged completely or predominantly in the depression 9 and/or that the difference between second level and first level is greater than the height of the cooling agent chamber 12 measured in the axial direction based on the center Z of the process chamber 2.

A CVD reactor, which is characterized in that the susceptor 3 can be rotationally driven around the center Z and/or that the circular disk-shaped substrate carriers 5 can be rotationally driven around their respective centers Z.

An annular body, which is characterized in that a surface portion 10, which runs on a hollow cone surface and, which, by forming a transition 22, transitions into a flat surface 11 extending all the way to the radially outer edge of the annular body 19, adjoins the radially inner edge of the annular body 19.

An annular body, which is characterized in that the transition 22 is a transition edge, which has a distance from the radially inner edge of the annular body 19, which corresponds to 40% to 60% of the width of the annular body 19 and/or that the annular body 19 has a radially inner wall 25, which extends on an inner cylinder surface and which has a height, which is smaller than 50% of the distance of the flat surface 11 from a flat underside 26 of the annular body 19.

All of the disclosed features (alone, but also in combination with one another) are essential for the invention. The disclosure content of the corresponding/enclosed priority documents (copy of the prior application) is herewith also included in its entirety in the disclosure of the application, also for the purpose of adding features of these documents into claims of the present application. With their features, the subclaims characterize, even without the features of a referenced claim, independent inventive further developments of the prior art, in particular in order to file divisional applications on the basis of these claims. The invention specified in each claim can additionally have one or several of the features, which are in particular provided with reference numerals in the above description and/or which are specified in the list of reference numerals. The invention also relates to designs, in the case of which individual features of the features mentioned in the above description are not realized, in particular insofar as they are evidently dispensable for the respective intended purpose or can be replaced by other technically equivalent means.

List of Reference Numerals

| | |
|---|---|
| 1 | gas inlet element |
| 2 | process chamber |
| 3 | susceptor |
| 3′ | process chamber floor |
| 4 | storage space |
| 5 | substrate carrier |
| 6 | substrate |
| 7 | process chamber ceiling |
| 7′ | underside |
| 8 | heating device |
| 9 | depression |
| 9′ | depression floor |
| 10 | first floor portion |
| 11 | second floor portion |
| 12 | cooling agent chamber |
| 13 | gas outlet wall |
| 14 | gas outlet opening |
| 15 | gas inlet zone |
| 15′ | gas inlet zone |
| 15″ | gas inlet zone |
| 16 | cooling agent duct |
| 17 | cooling agent duct |
| 18 | base body, plate |
| 19 | inner ring |
| 20 | cover element |
| 21 | central element, pulling plate |
| 22 | transition edge |
| 23 | separating wall |
| 24 | lower wall |
| 25 | wall |
| 26 | underside |
| H1 | height of the process chamber |
| H2 | height of the process chamber |
| P | process zone |
| V | feeder zone |
| S | flow direction |
| Z | center |
| a | extension length of the first floor portion |
| b | extension length of the feeder zone |
| c | distance between depression floor and underside of the gas inlet |
| | element |

1. A chemical vapor deposition (CVD) reactor comprising:
a process chamber (2); and
a gas inlet element (1) having a cooling device (12, 16, 17), and gas outlet openings (14) leading into the process chamber (2),
wherein the process chamber (2) has a feeder zone (V) directly adjoining the gas inlet element (1) and a process zone (P), which follows said feeder zone (V) in a flow direction (S) of a process gas entering the process chamber (2) from the gas outlet openings (14) and in which one or more storage spaces (14) for storing substrates (6) are arranged,
wherein the feeder zone (V) has a first floor portion (10), which directly adjoins the gas inlet element (1) and has a second floor portion (11), which is arranged between the first floor portion (10) and the process zone (P), and
wherein the first floor portion (10) rises over a radial length (a) of the first floor portion (10) in the flow direction (S) over at least 10% of a radial length (b) of the feeder zone (V) in a stair-shaped manner or as a bevel.

2. The CVD reactor of claim 1, wherein the first floor portion (10) at least one of:
(i) rises over the radial length (a) of the first floor portion (10) of at least 20% of the radial length (b) of the feeder zone (V); or
(ii) rises at an angle of 10 to 25 degrees from a first level, in which a depression floor (9′) of a depression (9) lies, into which the gas inlet element (1) protrudes, or in which a lower wall (24) of the gas inlet element (1) lies, to a second level, in which the second floor portion (11) lies.

3. The CVD reactor of claim 1, further comprising a process chamber ceiling (7), wherein a planar underside (7′) of the process chamber ceiling (7) has a first distance height (H1) at a beginning of the first floor portion (11), viewed in the flow direction (S), and a second distance height (H2) at an end of the first floor portion (11) or at a beginning of the second floor portion (11).

4. The CVD reactor of claim 1, further comprising:
a process chamber ceiling (7); and
substrate carriers (5) facing towards the process chamber (2), wherein a planar underside (7′) of the process chamber ceiling (7) runs parallel to a top side of the substrate carriers (5).

5. The CVD reactor of claim 1, further comprising a process chamber ceiling (7), wherein a distance between the process chamber ceiling (7) and the first floor portion (10) decreases continuously or gradually from a first distance height (H1) to a second distance height (H2) with increasing distance from the gas inlet element (1) over the radial length (a) of the first floor portion (10).

6. The CVD reactor of claim 1, further comprising substrate carriers (5), wherein the gas inlet element (1) is arranged in a center (Z) of the process chamber (2), the substrate carriers (5) are arranged annularly around the gas inlet element (1) in the process zone (P), and the first floor portion (10) forms an annular surface surrounding the gas inlet element (1).

7. The CVD reactor of claim 1, wherein a surface of the first floor portion (10) facing the process chamber (2) either runs in a smooth manner, or runs in a bending point-free manner, except for only one transition edge (22).

8. The CVD reactor of claim 1, further comprising a susceptor (3) with a base body (18), wherein the first floor portion (10) is formed by an inner ring (19) that is arranged around the gas inlet element (1) and rests on the base body (18) of the susceptor (3).

9. The CVD reactor of claim 1, wherein an inner ring (19) forming the first floor portion (10) is surrounded by one or more cover elements (20).

10. The CVD reactor of claim 1, wherein the first floor portion (10) is formed by a disk-shaped central element (21), which forms a depression (9) of uniform material, into which the gas inlet element (1) protrudes.

11. The CVD reactor of claim 1,
wherein the gas inlet element (1) has a plurality of gas inlet zones (15, 15′), which are arranged one on top of another and which each have gas outlet openings (14) arranged on a cylinder jacket surface,
wherein the gas outlet openings (14) are arranged in a gas outlet wall (13) of the gas inlet element (1) having one or more cooling agent ducts (17),
wherein a cooling agent chamber (12) is arranged below the plurality of gas inlet zones (15, 15′, 15″),
wherein a portion of the gas inlet element (1), in which the cooling agent chamber (12) lies, is arranged completely or predominantly in a depression (9), and
wherein a difference between a second level in which the second floor portion (11) lies and a first level in which a depression floor (9′) of the depression (9) lies is greater than a height of the cooling agent chamber (12) measured in an axial direction based on a center (Z) of the process chamber (2).

12. The CVD reactor of claim 1, further comprising:
a susceptor (3) configured to be rotationally driven around a center (Z) of the process chamber (2); and
circular disk-shaped substrate carriers (5) configured to be rotationally driven around their respective centers.

13. A method, comprising:
using an annular body (19) having an inner diameter and an outer diameter, in a chemical vapor deposition (CVD) reactor, the inner diameter of the annular body (19) being greater than an outer diameter of a gas inlet element (1) and the outer diameter of the annular body (19) being smaller than an inner diameter of a one- or multi-piece cover element (20); and
placing the annular body (19) onto a portion of a base body (18) surrounding the gas inlet element (10),
wherein a surface portion (10) of the annular body (19) adjoins a radially inner edge of the annular body (19), and
wherein the surface portion (10) of the annular body (19) runs on a hollow cone surface, and
wherein the surface portion (10) of the annular body (19) transitions, via a transition (22), into a flat surface (11) of the annular body (19) extending to a radially outer edge of the annular body (19).

14. The method of claim 13, wherein the transition (22) is a transition edge that is disposed a distance from the radially inner edge of the annular body (19), the distance corresponding to 40% to 60% of a width of the annular body (19).

15. The method of claim 13, wherein the annular body (19) has a radially inner wall (25) that extends on an inner cylinder surface and has a height which is less than 50% of a distance between the flat surface (11) of the annular body (19) and a flat underside (26) of the annular body (19).

16. (canceled)
